(19) United States
(12) Patent Application Publication
(10) Pub. No.: US 2013/0314854 A1
(43) Pub. Date: Nov. 28, 2013

(54) SURFACE CONTACT CARD HOLDER FOR ELECTRONIC DEVICE

(71) Applicants: SHENZHEN FUTAIHONG PRECISION INDUSTRY CO., LTD., Shenzhen (CN); FIH (HONG KONG) LIMITED, Kowloon (HK)

(72) Inventors: HUAN-CHANG CHUNG, Shindian (TW); YAN-LING GAO, Shenzhen (CN)

(73) Assignees: FIH (HONG KONG) LIMITED, Kowloon (HK); SHENZHEN FUTAIHONG PRECISION INDUSTRY CO., LTD., Shenzhen (CN)

(21) Appl. No.: 13/728,119

(22) Filed: Dec. 27, 2012

(30) Foreign Application Priority Data
May 28, 2012 (CN) 201210168010.7

(51) Int. Cl. H05K 5/02

(52) U.S. Cl. CPC H05K 5/0239
USPC 361/679.01; 312/330.1; 312/333

(57) ABSTRACT

A surface contact card holder includes a main body defining an entrance, a tray for receiving a surface contact card, and a cover attached to an end of the tray and releasably received in the entrance. The tray is slidably received in the main body through the entrance. The cover includes an operation board comprising elastic material. The tray has a supporting portion protruding from the end with the cover attached. When the operation board is pressed towards the tray, a portion of the operation board deforms to elastically resist the supporting portion, thus a free end of the operation board is raised up around the supporting portion to pivot away from the entrance.

### BACKGROUND

1. Technical Field

The present disclosure relates to surface contact card holders for electronic devices.

2. Description of related art

Commonly, portable electronic devices such as mobile phones include a surface contact card holder for holding a surface contact card, such as a subscriber identity module (SIM) card therein.

Conventional surface contact card holders include a tray assembled to the mobile phone. Although the conventional surface contact card holders may be simple, it can be difficult for the surface contact card to be removed from the surface contact card holder.

Therefore, there is room for improvement within the art.

### BRIEF DESCRIPTION OF THE DRAWINGS

Many aspects of the disclosure can be better understood with reference to the drawings. The components in the drawings are not necessarily drawn to scale, the emphasis instead being placed upon clearly illustrating the principles of the disclosure. Moreover, in the drawings, like reference numerals designate corresponding parts throughout the views.

FIG. 1 is an exploded, isometric view of a surface contact card holder in accordance with an exemplary embodiment.

FIG. 2 is an exploded, isometric view of the surface contact card holder of FIG. 1 viewed from another angle.

FIG. 3 is an assembled, isometric view of the surface contact card holder of FIG. 1.

FIG. 4 is a cut-away view of the surface contact card holder of FIG. 3 in a first state (taken along line IV-IV).

FIG. 5 is a cut-away view of the surface contact card holder of FIG. 3 in a second state (taken along line IV-IV).

### DETAILED DESCRIPTION

The disclosed surface contact card holder can seat surface contact cards such as SIM cards, compact flash cards, multimedia cards, and others. The disclosed electronic device, shown in the exemplary embodiment as a mobile phone, can alternatively be a personal digital assistant, camera, recorder, or other device remaining well within the scope of the disclosure.

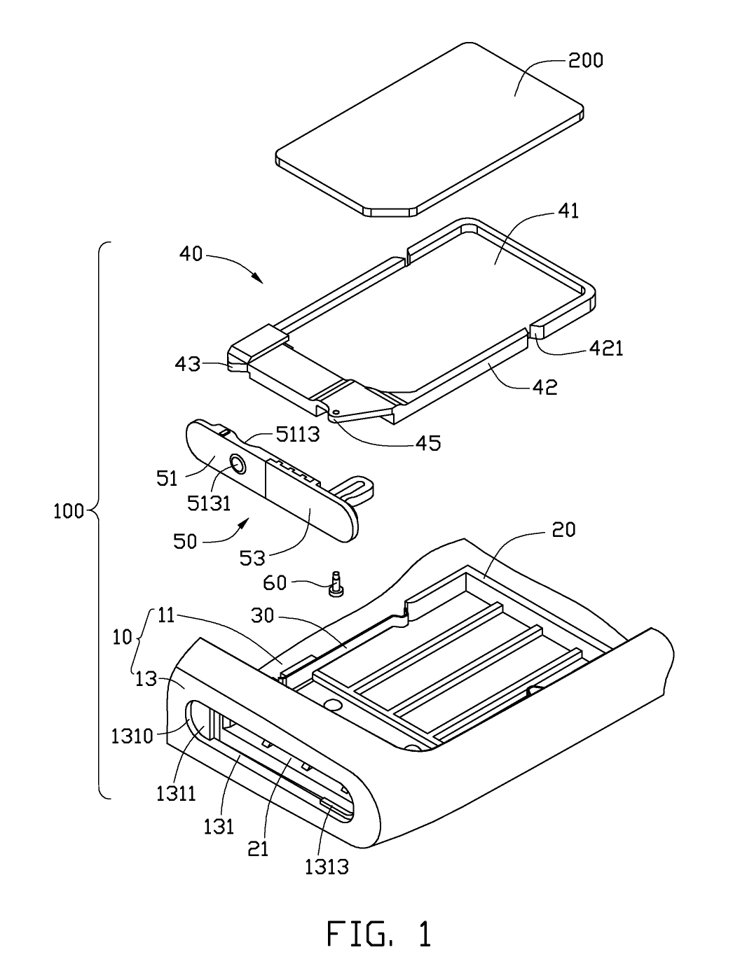

FIG. 1 shows an exemplary embodiment of a surface contact card holder 100 configured for receiving a surface contact card 200. The surface contact card holder 100 comprises a main body 10, a seat 20 secured in the main body 10, a latching member 30 assembled in the seat 20, a tray 40 releasably held by the latching member 30, and a cover 50 attached to the tray 40.

The main body 10 can be assembled in a housing of an electronic device or be integrally formed with the housing of the electronic device. In the exemplary embodiment, the main body 10 is integrally formed with the housing of the electronic device to be a portion of the housing. The main body 10 includes a bottom wall 11 and a peripheral wall 13 protruding from a peripheral edge of the bottom wall 11. The peripheral wall 13 defines an entrance 131 for mounting the cover 50. A first limiting portion 1311 and a second limiting portion 1313 protrude from an entrance sidewall 1310 of the entrance 131 and are substantially opposite to each other. When the cover 50 is mounted in the entrance 131, the first and second limiting portions 1311, 1313 resist against the cover 50, so as to prevent the cover 50 from dropping into the interior of the electronic device.

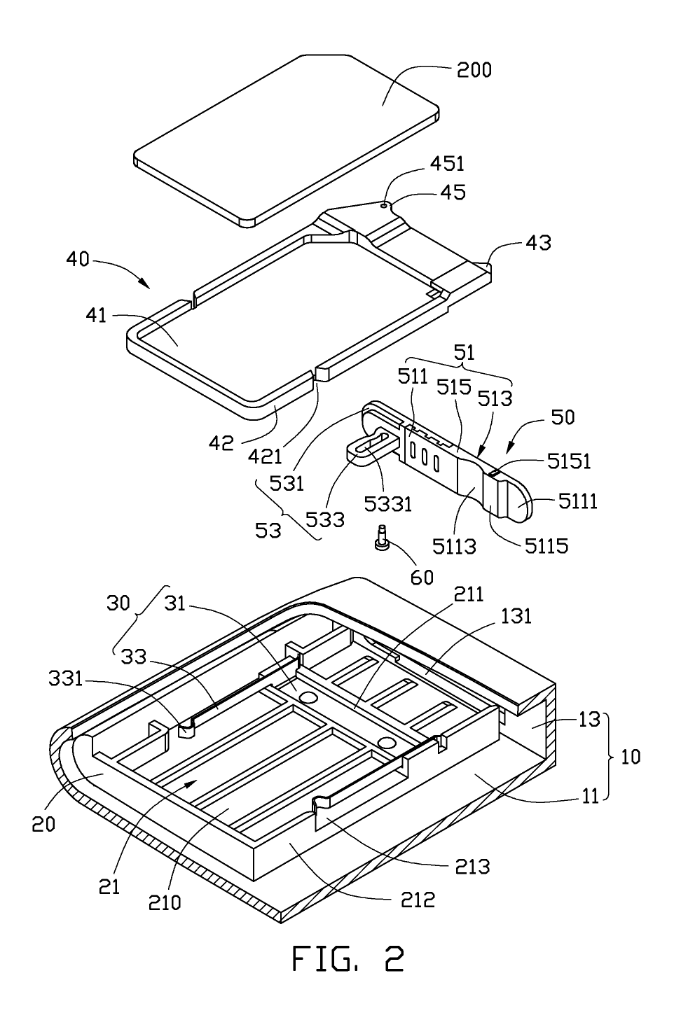

Referring to FIGS. 1 and 2, the seat 20 is attached to the bottom wall 11 nearby the peripheral wall 13. The seat 20 defines a receiving recess 21 communicating with the entrance 131, for receiving the tray 40 and the card 200 received in the tray 40. The seat 20 and the main body 10 may both be molded from plastic. The seat 20 and the main body 10 can be separately molded and then assembled together. Alternatively, the seat 20 and the main body 10 can be integrally molded as one part. A positioning recess 211 is defined in a bottom 210 of the receiving recess 21, for positioning the latching member 30. Two opening 213 are defined in two opposite receiving recess sidewalls 212 of the receiving recess 21.

The latching member 30 is a metal member and is positioned in the receiving recess 21, for holding the tray 40 in the receiving recess 21. The latching member 30 includes a connecting portion 31 and two flexible arms 33, extending perpendicularly from two ends of the connecting portion 31. The two flexible arms 33 are located on the same side of the connecting portion 31. The connecting portion 31 and the two flexible arms 33 all are sheet-shaped. The connecting portion 31 is fastened in the positioning recess 211, by heat-melting or by screws, for example. Each flexible arm 33 has a bent portion 331 protruding towards to the other flexible arm 33. In the exemplary embodiment, each bent portion 331 is formed at a distal end of each flexible arm 33, away from the connecting portion 31. The two bent portions 331 are opposite to each other and releasably resist the tray 40. In the exemplary embodiment, the two bent portions 331 are arcuate. The two openings 213 of the seat 20 are defined corresponding to the two flexible arms 33. When the free ends of the two flexible arms 33 flexibly deform to separate away from each other, the free ends can enter the openings 213.

Referring to FIGS. 1, 2 and 4, the tray 40 may be a metal member. The tray 40 has an accommodating recess 41, for accommodating the card 200. Two notches 421 are defined in a tray peripheral wall 42 of the tray 40 and are opposite to each other. The configuration of the notches 421 is corresponding to the bent portions 331. Each of the bent portions 331 is releasably latched in one of the notches 421. When the tray 40 is received in the receiving recess 21, the tray 40 is clamped between the two flexible arms 33, with the bent portions 331 latched in the notches 421. The tray 40 further has a supporting portion 43 and a flange portion 45 protruding from an end facing the cover 50 and spaced from each other. The supporting portion 43 is substantially a triangular block in the exemplary embodiment. In other embodiments, the supporting portion 43 can be other shapes, such as a cylinder. The flange portion 45 is configured for fastening the cover 50 to the tray 40. The flange portion 45 has a hole 451 for securing a fastening member 60 therein to fasten the cover 50 to the tray 40. In the exemplary embodiment, the fastening member 60 is a screw bolt.

The cover 50 includes an operation board 51 and a fastening board 53 attached to the operation board 51. In the exemplary embodiment, the operation board 51 and the fastening board 53 are integrally formed to be one part by a double-shot molding process. The operation board 51 is made of elastic material, such as rubber. In one embodiment, the operation board 51 is made of thermoplastic polyurethane. The fastening board 53 is made of plastic.

The operation board 51 resists the supporting portion 43 under an outside force, and can swing around the supporting portion 43 to enable one end of the operation board 51 withdraw from the entrance 131. The operation board 51 includes an inner surface 511, an outer surface 513 opposite to the inner surface 511, and two side surfaces 515 connecting with the inner surface 511 and the outer surface 513. When the cover 50 is assembled to the tray 40, the inner surface 511 faces the tray 40. The operation board 51 has a resisting portion 5115 protruding from the inner surface 511, and has a handle 5111 and a operation portion 5113 formed at two ends of the resisting portion 5115. The handle portion 5111 is a free end of the operation board 51 and has a thickness less than a thickness of the resisting portion 5115. The operation portion 5113 is recessed in the inner surface 511, causing the thickness of the operation portion 5113 to be less than the thickness of the resisting portion 5115. Thus, the operation portion 5113 is spaced from the tray 40, to provide a space for elastic deformation of the operation portion 5113 under an outside pressure. The resisting portion 5115 is aligned with the supporting portion 43 of the tray 40.

The outer surface 513 has an indicating mark 5131 (see FIG. 1) corresponding to the operation portion 5113, to indicate the position of the operation portion 5113. When the outer surface 513 is pressed at the position of the indicating mark 5131 by an outside force towards the tray 40, the operation portion 5113 is compressed to elastically deform and bend towards the tray 40, bringing the resisting portion 5115 to resist the supporting portion 43. In this case, the handle portion 5111 is raised up from the entrance 131. The cover 50 with the tray 40 can be pulled out of the main body 10 by pulling the handle portion 5111. In the exemplary embodiment, the indicating mark 5131 is a protrudent circle. The indicating mark 5131 can also be characters or patterns in other embodiments.

Each of the side surfaces 515 has a protruding trip 5151 protruding therefrom. When the cover 50 is mounted in the entrance 131, an interference fit exists between the protruding trips 5151 and the entrance sidewall 1310, to steady assemble the cover 50 in the entrance 131.

The fastening board 53 connects the operation board 51 at a first end. The fastening board 53 has a retaining portion 531 formed at a second end and a protruding block 533 protruding towards the tray 40. The retaining portion 531 abuts against the second limiting portion 1313. The protruding block 533 has a mounting hole 5331. The fastening member 60 movably extends through the mounting hole 5331 to be secured into the hole 451 of the tray 40, thus connecting the tray 40 and the cover 50. The mounting hole 5331 is substantially strip-shaped. During the process of pulling the cover 50 out of the entrance 131, the fastening member 60 can move in the mounting hole 5331.

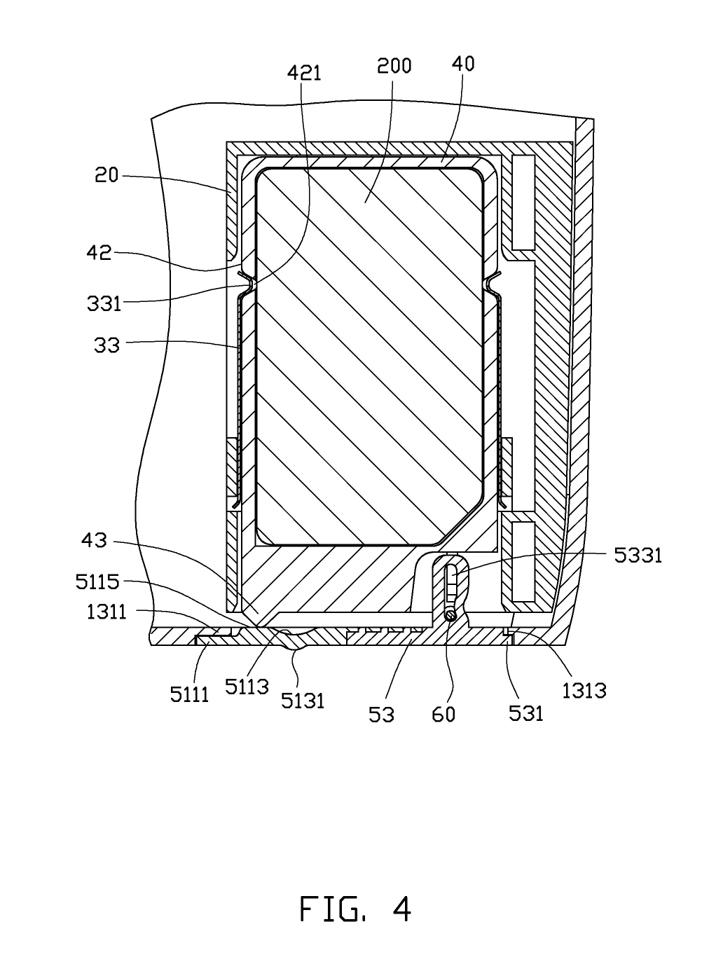

Referring to FIG. 1 and FIG. 4, to assemble the surface contact card holder 100, the fastening member 60 is inserted through the mounting hole 5331 of the cover 50 and secured into the hole 451 of the tray 40, thereby assembling the cover 50 to the tray 40. Then, the tray 40 is pushed into receiving recess 21 through the entrance 131. The tray 40 is clamped between the two flexible arms 33 of the latching member 30, with the bent portions 331 latched in the notches 421 of the tray 40. The cover 50 is received in the entrance 131.

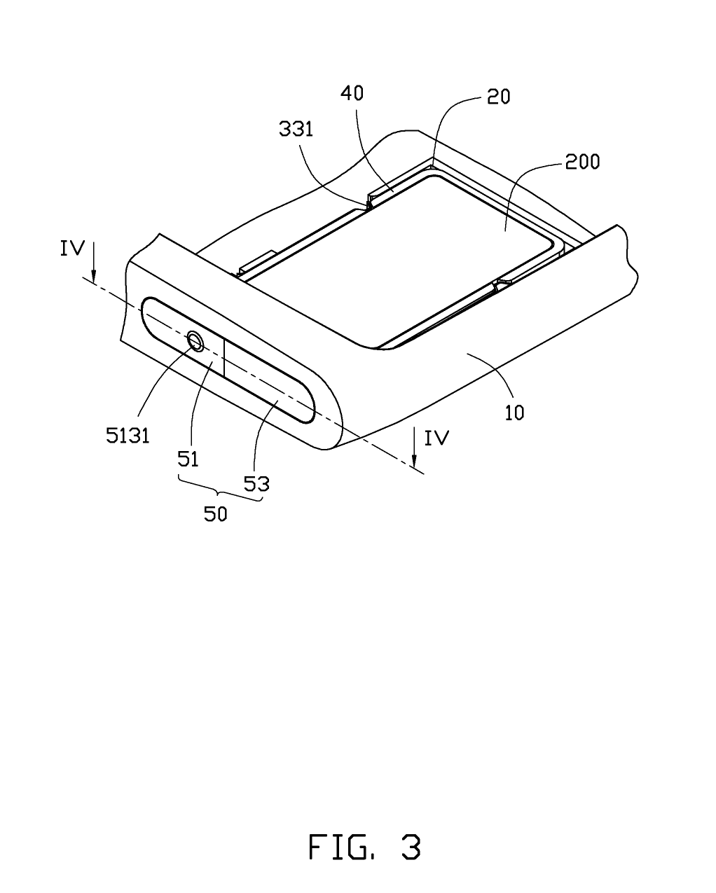

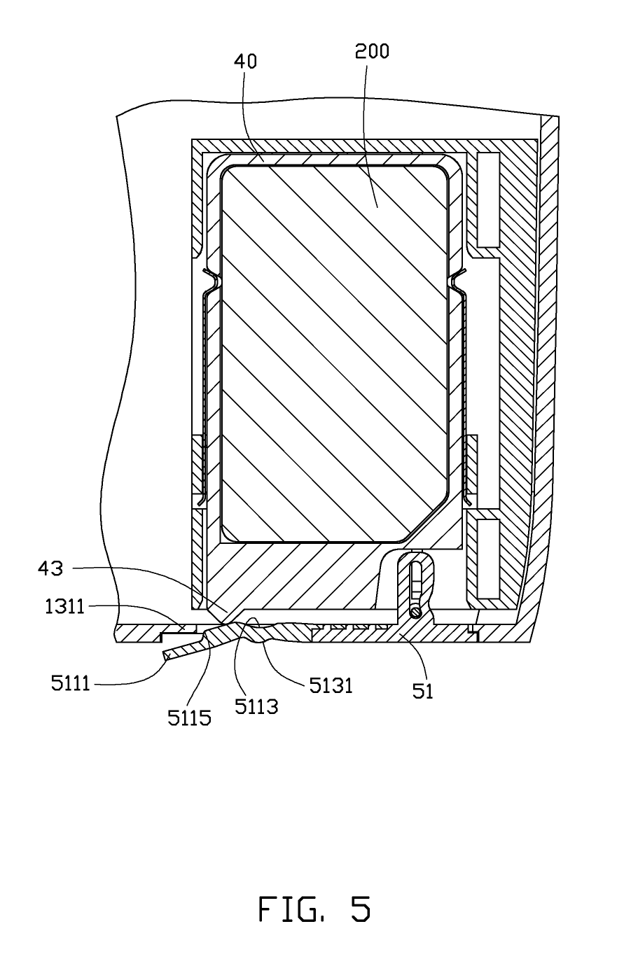

Referring to FIG. 3 through FIG. 5, to mount the card 200 into the holder 100 or change the card 200, the indicating mark 5131 position of the outer surface 513 of the operation board 51 is pressed towards the tray 40, and the operation portion 5113 is compressed to elastically deform and bend towards the tray 40, bringing the resisting portion 5115 to resist the supporting portion 43. In this case, the handle portion 5111 is raised up around the supporting portion 43 to pivot away from the entrance 131. The cover 50, with the tray 40, can be pulled out of the main body 10 by pulling the handle portion 5111. The card 200 can be inserted into the accommodating recess 41 of the tray 40, or can be taken out to be changed. To close the holder 100, the tray 40 is pushed into the receiving recess 21 until the two bent portions 331 of the latching member 30 are latched in the two notches 421 of the tray 40. At this time, the cover 50 is received in the entrance 131.

It is to be understood, however, that even through numerous characteristics and advantages of the present disclosure have been set forth in the foregoing description, together with details of assembly and function, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. A surface contact card holder, comprising:
a main body, the main body defining an entrance;
a tray for receiving a surface contact card, the tray slidably received in the main body through the entrance; and
a cover attached to an end of the tray and releasably received in the entrance, and the cover comprises an operation board comprising elastic material;
wherein the tray has a supporting portion protruding from said end, when the operation board is pressed toward the tray, a portion of the operation board deforms to elastically resist the supporting portion, thus a free end of the operation board is raised up from the entrance.

2. The holder as claimed in claim 1, wherein the operation board comprises an inner surface facing the tray, an outer surface opposite to the inner surface, a resisting portion protruding from the inner surface, and a handle portion and an operation portion connecting two ends of the resisting portion; and the operation portion is recessed in the inner surface to be spaced from the tray; and the handle portion is the free end of the operation board.

3. The holder as claimed in claim 2, wherein the outer surface has an indicating mark, corresponding to the operation portion, to facilitate an outer force being applied to the operation board.

4. The holder as claimed in claim 2, wherein the operation board further has protruding strips protruding therefrom; and when the cover is mounted in the entrance, an interference fit exists between the protruding strips and a sidewall of the entrance.

5. The holder as claimed in claim 1, wherein the cover further comprises a fastening board comprising plastic and connected to the operation board at a first end.

6. The holder as claimed in claim 5, wherein the operation board and the fastening board are integral.

7. The holder as claimed in claim 6, further comprising a fastening member; wherein the tray has a flange portion protruding from said end; the flange portion defines a hole; the operation board has a protruding block protruding towards the tray; the protruding block defines a mounting hole; the fastening member movably extends through the mounting hole to be secured into the hole, thus fastening the cover to the tray.

8. The holder as claimed in claim 1, further comprising a latching member; wherein the latching member comprises a connecting portion and two flexible arms extending perpendicularly from two ends of the connecting portion and located on the same side of the connecting portion, a flexible arm free end of each flexible arm bending to be a bent portion protruding towards to the other flexible arm; wherein the tray has two notches defined in a peripheral wall of the tray and opposite to each other; each of the bent portions is releasably latched in one of the notches.

9. The holder as claimed in claim 8, further comprising a seat secured in the main body; wherein the seat defines a receiving recess communicating with the entrance, and has a positioning recess defined in a bottom of the receiving recess; and the connecting portion of the latching member is fastened in the positioning recess.

10. The holder as claimed in claim 1, wherein the main body has limiting portions protruding from a sidewall of the entrance; and when the cover is mounted in the entrance, the limiting portions resist the cover to prevent the cover from dropping into the main body.

11. An electronic device comprising a surface contact card holder, the surface contact card holder mounted on the electronic device and comprising:
a main body, the main body defining an entrance;
a tray for receiving a surface contact card, the tray slidably received in the main body through the entrance; and
a cover attached to an end of the tray and releasably received in the entrance, and the cover comprises an operation board comprising elastic material;
wherein the tray has a supporting portion protruding from said end, when the operation board is pressed toward the tray, a portion of the operation board deforms to elastically resist the supporting portion, thus a free end of the operation board is raised up from the entrance.

12. The electronic device as claimed in claim 11, wherein the operation board comprises an inner surface facing the tray, an outer surface opposite to the inner surface, a resisting portion protruding from the inner surface, and a handle portion and an operation portion connecting two ends of the resisting portion; and the operation portion is recessed in the inner surface to be spaced from the tray; and the handle portion is the free end of the operation board.

13. The electronic device as claimed in claim 12, wherein the outer surface has an indicating mark, corresponding to the operation portion, to facilitate an outer force being applied to the operation board.

14. The electronic device as claimed in claim 12, wherein the operation board further has protruding strips protruding therefrom; and when the cover is mounted in the entrance, an interference fit exists between the protruding strips and a sidewall of the entrance.

15. The electronic device as claimed in claim 11, wherein the cover further comprises a fastening board comprising plastic and connected to the operation board at a first end.

16. The electronic device as claimed in claim 15, wherein the operation board and the fastening board are integral.

17. The electronic device as claimed in claim 16, further comprising a fastening member; wherein the tray has a flange portion protruding from said end; the flange portion defines a hole; the operation board has a protruding block protruding towards the tray; the protruding block defines a mounting hole; the fastening member movably extends through the mounting hole to be secured into the hole, thus fastening the cover to the tray.

18. The electronic device as claimed in claim 11, further comprising a latching member; wherein the latching member comprises a connecting portion and two flexible arms extending perpendicularly from two ends of the connecting portion and located on the same side of the connecting portion, a flexible arm free end of each flexible arm bending to be a bent portion protruding towards to the other flexible arm; wherein the tray has two notches defined in a peripheral wall of the tray and opposite to each other; each of the bent portions is releasably latched in one of the notches.

19. The electronic device as claimed in claim 18, further comprising a seat secured in the main body; wherein the seat defines a receiving recess communicating with the entrance, and has a positioning recess defined in a bottom of the receiving recess; and the connecting portion of the latching member is fastened in the positioning recess.

20. The electronic device as claimed in claim 11, wherein the main body has limiting portions protruding from a sidewall of the entrance; and when the cover is mounted in the entrance, the limiting portions resist the cover to prevent the cover from dropping into the main body.
